(19) United States
(12) Patent Application Publication
(10) Pub. No.: US 2011/0086462 A1
(43) Pub. Date: Apr. 14, 2011

(54) Process for Manufacturing Solar Cells including Ambient Pressure Plasma Torch Step

(76) Inventor: Stanford R. Ovshinsky, Bloomfield Hills, MI (US)

(21) Appl. No.: 12/575,859

(22) Filed: Oct. 8, 2009

(51) Int. Cl. H01L 31/0232

(52) U.S. Cl. 438/72; 257/E31.127

(57) ABSTRACT

A method of forming photovoltaic devices and modules that includes an ambient pressure thin film deposition step. The central combination of the photovoltaic device structure includes a back reflector layer, active photovoltaic material and transparent electrode. The central combination is formed on a substrate having an electrical isolation layer deposited thereon. The device structure may further include an overlying protective layer remote from the substrate and a laminate on the backside of the substrate. The individual devices may be interconnected in series via a patterning process to form a monolithically integrated module. Module fabrication is preferably performed in a continuous fashion. One or more steps of module fabrication are performed with a plasma torch. Use of a plasma torch simplifies the manufacturing process by enabling deposition of the electrical isolation and/or protective layers at ambient pressure, including in air. The resulting process simplification greatly improves the economics of thin film photovoltaic module manufacturing.

### FIELD OF INVENTION

This invention relates to the high speed manufacturing of photovoltaic materials. More particularly, this invention relates to a manufacturing process for fabricating multilayer solar cell device that includes deposition of one or more layers at ambient conditions utilizing a plasma torch source.

### BACKGROUND OF THE INVENTION

Concern over the depletion and environmental impact of fossil fuels has stimulated strong interest in the development of alternative energy sources. Significant investments in areas such as batteries, fuel cells, hydrogen production and storage, biomass, wind power, algae, and solar energy have been made as society seeks to develop new ways of creating and storing energy in an economically competitive and environmentally benign fashion. The ultimate objective is to minimize society's reliance on fossil fuels and to do so in an economically competitive way that minimizes greenhouse gas production.

A number of experts have concluded that to avoid the serious consequences of global warming, it is necessary to maintain CO₂ at levels of 550 ppm or less. To meet this target, based on current projections, the world will need 17 TW of carbon-free energy by the year 2050 and 33 TW by the year 2100. The estimated contributions of various carbon-free sources toward the year 2050 goal are summarized below:

| Source | Projected Energy Supply (TW) |
|---|---|
| Wind | 2-4 |
| Tidal | 2 |
| Hydro | 1.6 |
| Biofuels | 5-7 |
| Geothermal | 2-4 |
| Solar | 600 |

Based on the expected supply of energy from the available carbon-free sources, it is apparent that solar energy is the only viable solution for reducing greenhouse emissions and alleviating the effects of global climate change.

Unless solar energy becomes cost competitive with fossil fuels, however, society will lack the motivation to eliminate its dependence on fossil fuels and will refrain from adopting solar energy on the scale necessary to meaningfully address global warming. As a result, current efforts in manufacturing are directed at reducing the unit cost (cost per kilowatt-hour) of energy produced by photovoltaic materials and products. The general strategies for decreasing the unit cost of energy include reducing process costs and improving photovoltaic efficiency. Efforts at reducing process costs are directed to identifying low cost photovoltaic materials, increasing process speeds, and simplifying process steps.

Crystalline silicon is currently the dominant photovoltaic material because of its wide availability in bulk form. Crystalline silicon, however, possesses weak absorption of solar energy because it is an indirect gap material. As a result, photovoltaic modules made from crystalline silicon are thick, rigid and not amenable to lightweight, thin film products.

Amorphous silicon (and hydrogenated and/or fluorinated forms thereof) is an attractive photovoltaic material for lightweight, efficient, and flexible thin-film photovoltaic products. The instant inventor, Stanford R. Ovshinsky, is a leading figure in modern thin film semiconductor technology. Early on, he recognized the advantages of amorphous silicon (as well as amorphous germanium, amorphous alloys of silicon and germanium, including doped, hydrogenated and fluorinated versions thereof) as a solar energy material. He also recognized the advantages of nanocrystalline silicon as a photovoltaic material and was among the first to understand the physics and practical benefits of intermediate range order materials and multilayer photovoltaic devices. For representative contributions of S. R. Ovshinsky in the area of photovoltaic materials see U.S. Pat. No. 4,217,374 (describing suitability of amorphous silicon and related materials as the active material in several semiconducting devices); U.S. Pat. No. 4,226,898 (demonstration of solar cells having multiple layers, including n- and p-doped); and U.S. Pat. No. 5,103,284 (deposition of nanocrystalline silicon and demonstration of advantages thereof); as well as his article entitled “The material basis of efficiency and stability in amorphous photovoltaics” (Solar Energy Materials and Solar Cells, vol. 32, p. 443-449 (1994)).

Approaches for increasing process speed include: (1) increasing the intrinsic deposition rates of the different materials and layers used to manufacture photovoltaic devices and (2) adopting a continuous, instead of a batch, manufacturing process. S. R. Ovshinsky has innovated the automated and continuous manufacturing techniques needed to produce thin film, flexible large-area solar panels based on amorphous, nanocrystalline, microcrystalline, polycrystalline or composite materials. Although his work has emphasized the silicon and germanium systems, the manufacturing techniques that he has developed are universal to all material systems. Representative contributions of S. R. Ovshinsky to the field of photovoltaic manufacturing are included in U.S. Pat. No. 4,400,409 (describing a continuous manufacturing process for making thin film photovoltaic films and devices); U.S. Pat. No. 4,410,588 (describing an apparatus for the continuous manufacturing of thin film photovoltaic solar cells); U.S. Pat. No. 4,438,723 (describing an apparatus having multiple deposition chambers for the continuous manufacturing of multilayer photovoltaic devices); and U.S. Pat. No. 5,324,553 (microwave deposition of thin film photovoltaic materials).

Amorphous silicon-based photovoltaic devices are typically multilayer structures that include a substrate, back reflector, lower electrode, active photovoltaic material based on amorphous silicon or an alloy or modified form thereof, upper electrode, and a protective layer. Operation of the device entails absorption of solar energy by the active photovoltaic material to form mobile charge carriers (electrons and holes) that are separated and directed to the surrounding electrodes to provide a current to an external load. In order to function, it is necessary for incident light to pass through the device structure to reach the active photovoltaic material. The required transmissivity of the device structure may be achieved through the use of a transparent substrate (e.g. glass) and/or through use of an electrode remote from the substrate formed from a transparent conductive material along with a transparent protective layer.

The prevailing commercial process for manufacturing amorphous silicon-based photovoltaic products utilizes a plasma deposition technique. A gas phase precursor, typically silane (SiH₄), is delivered to a plasma deposition chamber and activated to a plasma state. Activation occurs by directing the precursor to the region between an anode and cathode and applying a sufficiently high voltage. The plasma is typically formed in the presence of an inert background gas (such as argon). Activation of the precursor creates a deposition medium that subsequently reacts or otherwise evolves to form a thin film of amorphous silicon on an adjacent substrate. The activation process transforms the precursor to a state that is more conducive to formation of amorphous silicon and leads to an enhancement in the deposition rate.

The leading prior art process for manufacturing amorphous silicon-based photovoltaic products is a continuous deposition process that uses a web of stainless steel as a substrate. Utilization of a moving, continuous web substrate increases the overall manufacturing speed and provides economic efficiencies. Metal substrates are desirable because they are durable and not prone to damage during web transport at high speeds. Metal substrates are also beneficial because they it can be configured to function as an electrode in plasma deposition processes.

A drawback of the leading commercial process, however, is the need to perform the deposition under vacuum conditions. The process line includes a payout roller for delivering the substrate to a deposition apparatus that includes a series of operatively interconnected chambers for depositing a series of thin film layers and a take up roller for receiving the substrate after the deposition is complete. Typically a separate chamber is dedicated to the deposition of each layer of a multilayer photovoltaic structure. The deposition apparatus, from the point of entry of the bare substrate to the point of exit of the completed multilayer photovoltaic structure, is maintained at low pressure or vacuum conditions.

Establishing low pressure or vacuum conditions over the volume of the process requires powerful pumps and adds complexity to the process units. Operating costs of the process are correspondingly high. There is a need to develop new continuous manufacturing processes for the fabrication of amorphous silicon-based photovoltaic products that minimize the need for vacuum or low pressure conditions.

### SUMMARY OF THE INVENTION

This invention provides a method and apparatus for manufacturing thin film photovoltaic devices and modules. The device structure includes a substrate, an isolation layer, a back reflector layer, an active photovoltaic material, and a transparent electrode. The device structure may also include a protective layer, a backside laminate, and overlying package electrodes or grid lines.

The substrate may be a metal, glass, or a plastic. The isolation layer is a dielectric layer that provides electrical isolation of the active thin film material from the substrate and is especially beneficial when a conductive substrate is employed. The back reflector is an optically reflective, conductive material that also serves as an electrode for the device. Representative back reflectors include metals, dielectrics oxides and combinations thereof such as Al, Ag, ZnO, ZnS, ZnO/Al, and ZnS/Al. The protective layer is an overlying layer that prevents deterioration of the underlying layers due to causes such as moisture, oxidation, or photobleaching. Representative protective layers include silicon-based polymers (e.g. silicone, polysiloxane) or carbon-based polymers (e.g. Teflon, Tefcell, polyethylene, polycarbonate, ethylvinylacetate). Representative materials for the laminate include plastics and fiberglass.

Preferred active thin film materials include semiconductor materials and photovoltaic materials having a bandgap that is capable of absorbing at least a portion of the solar spectrum. Representative photovoltaic materials include CdS, CdSe, CdTe, ZnTe, ZnSe, ZnS, CIGS (Cu—In—Ga—Se and related alloys), organic materials (including organic dyes), and TiO₂ or other metal oxides, including doped or activated forms thereof. Silicon-based photovoltaic materials include amorphous silicon (a-Si), alloys of amorphous silicon (e.g. amorphous silicon-germanium alloys), nanocrystalline silicon, nanocrystalline alloys of silicon, microcrystalline silicon, microcrystalline alloys of silicon. Silicon-based photovoltaic materials include fluorinated or hydrogenated forms thereof. Silicon-based photovoltaic materials may also include n-type or p-type dopants.

The photovoltaic material may also include multiple layers or multiple junctions. Multilayer photovoltaic materials may include n-type, i-type (intrinsic type), p-type layers, or combinations thereof including p-n or p-i-n type device structures. Two or more p-i-n (or n-i-p) structures may be stacked in series to achieve multiple junction device structures.

The fabrication process is completed partially under low pressure or vacuum conditions and partially at ambient conditions. In one embodiment, the active thin film material is formed under low pressure or vacuum conditions via a plasma deposition process and at least one surrounding layer is formed at ambient pressure. In one embodiment, the layer formed at ambient pressure is an electrical isolation layer (e.g. an oxide or nitride). In another embodiment, the layer formed at ambient pressure is a protective layer. The ambient pressure deposition step may be performed in air. Utilization of ambient conditions for one or more deposition steps improves process economics.

In one embodiment, the ambient pressure deposition step is accomplished with a plasma torch. The plasma torch is similar to a remote plasma source and includes two internal electrodes for establishing a plasma from a source gas deposition. A fresh supply of the source gas is continuously introduced to the plasma region of the plasma torch and activated to a plasma state. The source gas subsequently exits the plasma region and deactivates to an energized state that may then be used to form a thin film material. The plasma torch and deposition chamber may be interconnected by an orifice or nozzle.

In an alternative embodiment, the plasma region of the plasma torch is established between an internal electrode and a backplane electrode. The source gas is continuously introduced to the plasma region of the plasma torch and is activated to a plasma state. The backplane electrode forms a boundary of the plasma torch and includes an orifice or nozzle for interfacing the plasma torch with a deposition chamber. A pressure differential is established between the plasma region and deposition chamber to provide a driving force for drawing the activated source gas into the deposition chamber through the orifice or nozzle of the backplane electrode. As the source gas enters the deposition chamber, it deactivates to an energized state and is directed to a substrate or deposition surface for deposition of a thin film material. In a further embodiment, a nozzle interconnecting the plasma torch and deposition chamber may serve as an electrode for forming a plasma from a source gas. The source gas subsequently exits the plasma region through the nozzle and deactivates to an energized state from which a thin film material is formed.

The fabrication process may further include steps for patterning the back reflector, photovoltaic material, and transparent electrode layers to segment the layers into individual devices. The individual devices may subsequently be connected in series to achieve monolithic integration. Patterning may be accomplished by laser scribing or through one or more masking and etching procedures.

### BRIEF DESCRIPTION OF THE DRAWING

FIG. 1 depicts a photovoltaic module that includes a plurality of monolithically integrated photovoltaic devices.

FIGS. 2A-2M depict the device of FIG. 1 at various stages of fabrication.

FIGS. 3A-3B depict representative ways of depositing a thin film material with a plasma torch.

### DETAILED DESCRIPTION OF THE ILLUSTRATED EMBODIMENTS

Although this invention will be described in terms of certain preferred embodiments, other embodiments that are apparent to those of ordinary skill in the art, including embodiments that do not provide all of the benefits and features set forth herein and including embodiments that provide positive benefits for high-volume manufacturing, are also within the scope of this invention. Accordingly, the scope of the invention is defined only by reference to the appended claims.

As used herein, “on” signifies direct contact of a particular layer with another layer and “over” signifies that a particular layer is mechanically supported by another layer. If a particular layer, for example, is said to be formed on a substrate, the layer directly contacts the substrate. If a particular layer is said to be formed over a substrate, the layer is mechanically supported by the substrate and may or may not make direct contact with the substrate. If a particular layer is said to be formed on another layer, the particular layer directly contacts the other layer. If a particular layer is said to be formed over another layer, the particular layer is supported by the other layer and may or may not contact the other layer.

This invention provides a method and apparatus for producing multilayer photovoltaic device structures on continuous or stationary substrates. The photovoltaic device structures incorporate an amorphous, nanocrystalline, or microcrystalline semiconductor as the active photovoltaic material along with one or more surrounding layers. The active photovoltaic material is preferably formed in a plasma deposition process. As has been demonstrated by the instant inventor, plasma processes can be controlled to provide active photovoltaic materials having unique microstructures, novel chemical and physical properties, and superior performance characteristics. In addition to the active photovoltaic material, the device structures of the instant invention may further include one or more of the following surrounding layers: an isolation layer, a back reflector layer, conductive layer, dielectric layer, or protective layer.

Although the formation and stabilization of the plasma used for the deposition of the active photovoltaic material necessitate low pressure or vacuum conditions, the instant invention contemplates accomplishing the deposition of one or more of the accompanying layers at ambient pressure and/or in the presence of air. Inclusion of at least one deposition step under conditions not requiring reduced pressure simplifies manufacturing of photovoltaic devices relative to prior art processes and advances the economic competitiveness of solar energy.

The principles of the instant invention extend to both batch and continuous web manufacturing. In batch processing, deposition of one or more layers of a photovoltaic device occurs sequentially on individual wafers or substrates. Each wafer or substrate is handled separately and generally has a maximum lateral dimension on the order of several inches to a few feet. In batch processing, the wafer or substrate may be held stationary during deposition of a particular layer or may be in motion. A series of discrete substrates may be aligned along a manufacturing line and advanced continuously or intermittently through the deposition system.

In continuous web deposition, the substrate is a mobile, extended web that is continuously conveyed through a series of deposition or processing units. The web typically has a dimension of a few inches to a few feet in the direction transverse to the direction of transport of the web through the manufacturing apparatus. The dimension of the web in the direction of transport typically ranges from a few hundred to a few thousand feet. In continuous manufacturing, the web is generally in motion during deposition and processing of the individual layers of a multilayer device structure. The web of substrate material may be continuously advanced through a succession of one or more operatively interconnected deposition chambers, where each chamber is dedicated to the deposition of a particular layer or layers of a photovoltaic device structure. A sequence of layers is formed on the substrate to build a multilayer structure. The individual deposition chambers are environmentally protected to protect intermixing of the deposition media formed or introduced into the individual chambers. Gas gates, for example, may be placed between the chambers to prevent intermixing. The series of chambers may also include chambers dedicated to processes such as patterning, segmenting, scribing, masking, heating, annealing, cleaning, or substrate removal.

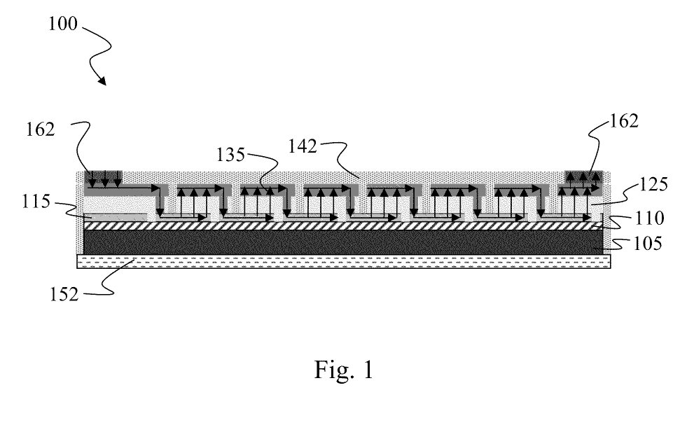

An illustrative monolithically integrated multilayer photovoltaic module in accordance with the instant invention is shown in FIG. 1. Module 100 includes substrate 105 with isolation layer 110 and patterned back reflector regions 115. Patterned regions 125 of an active photovoltaic are formed on patterned back reflector regions 115. Patterned transparent electrodes 135 are formed on pattered photovoltaic regions 125. Module 100 is finished by adding protective layer 142, backside laminate 152, and package electrodes 162. Module 100 includes a plurality of photovoltaic devices connected in series, where the arrows indicate the pathway of current flow.

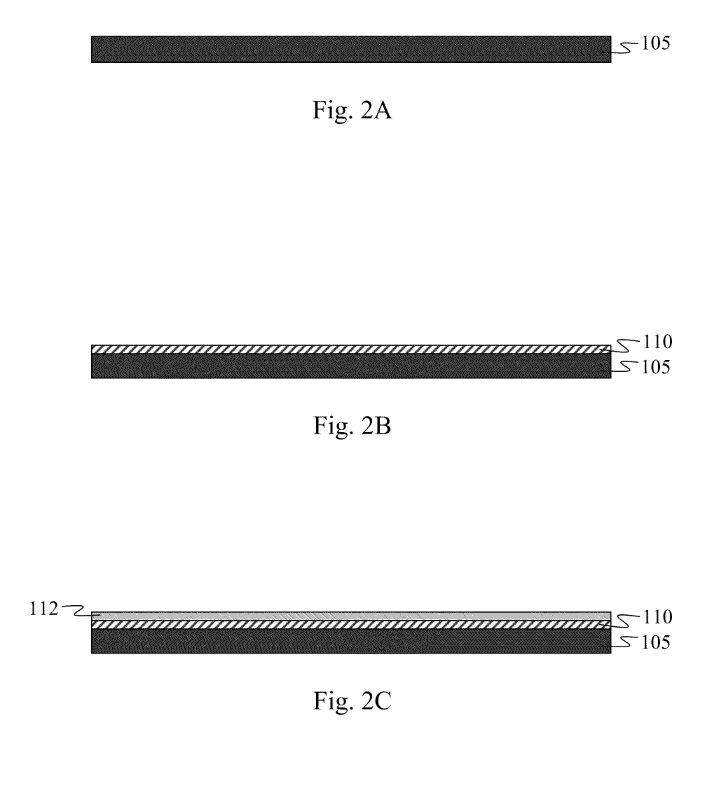

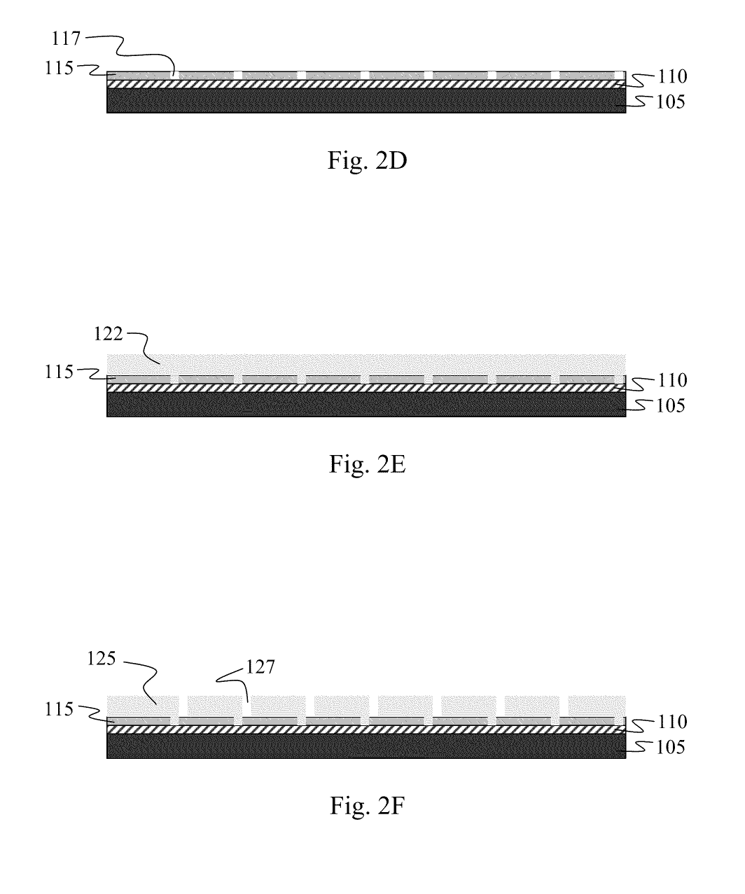

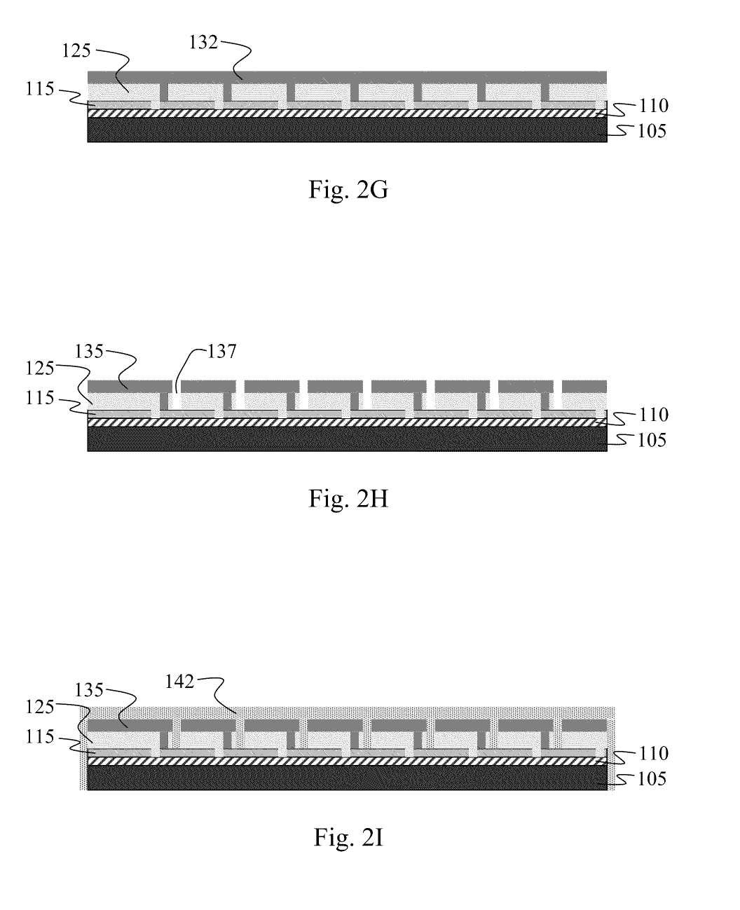

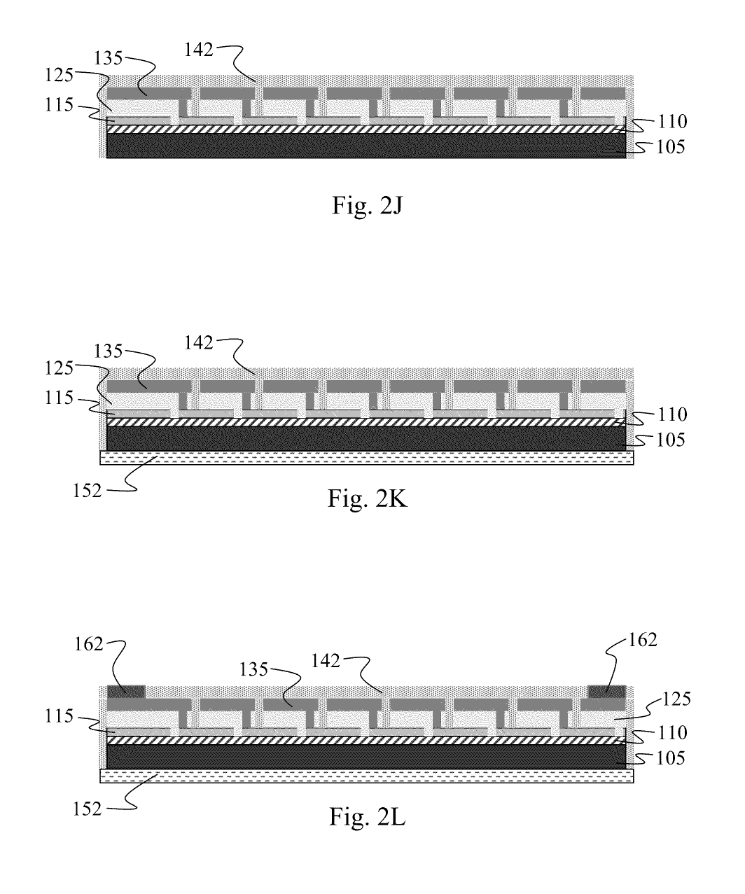

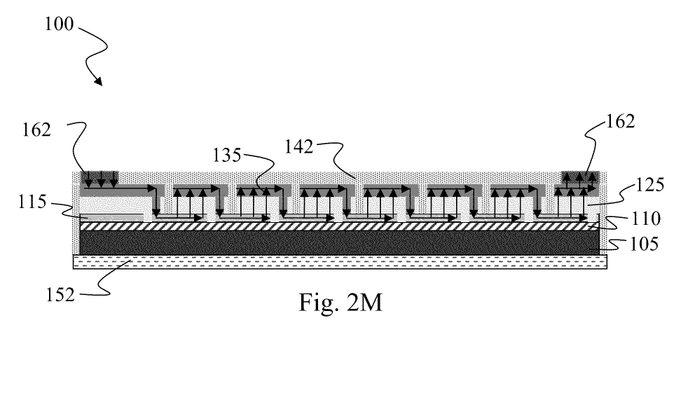

The processing and materials used in fabricating module 100 are now described. Processing begins with substrate 105 shown in FIG. 2A. Substrate 105 is a mechanically stable material having sufficient durability to withstand the deposition conditions associated with the formation of the individual layers in the device structure. Preferably the substrate is sufficiently durable to withstand rapid transport in a high speed continuous manufacturing process. Substrate 105 may be a metal, metal alloy, composite, polymer, or plastic substrate. Representative substrates include steel, aluminum, silicon, glass, Kevlar, Mylar, Kapton or other polyimide, mylar, Plexiglas, and polyethylene.

Isolation layer 110 is next deposited on substrate 105 (FIG. 2B). Isolation layer 110 is an insulator or dielectric material that is used to electrically isolate substrate 105 from the active photovoltaic material and other conductive layers of module 100. Inclusion of isolation layer 110 is most beneficial when substrate 105 is a conductive material, but may also provide a benefit for non-conducting substrates by preventing a charge buildup on the surface of the substrate. Many plastics, for example, can develop a static surface charge through handling or exposure to an electric field. Representative materials for isolation layer 110 include metal oxides (e.g. Al₂O₃), SiO₂, silicon nitride (SiNₓ, Si₃N₄) and silicon oxynitride.

In accordance with the instant invention, isolation layer 110 may be formed at ambient pressure without the need for vacuum or other reduced pressure conditions. As used herein, ambient pressure refers to the prevailing environmental pressure at the location of manufacturing. The environmental pressure is also referred to as atmospheric pressure, where it is understood that atmospheric pressure refers to the prevailing local pressure, as measured by a barometer, and may differ from the formal pressure of 1 atmosphere. In one embodiment, isolation layer 110 is formed in directly in air. Deposition of isolation layer 110 at ambient pressure simplifies the manufacturing process by eliminating the need for a deposition chamber equipped with pumps, vacuum equipment, or a special surrounding environment adapted to the chemical or physical characteristics of the isolation layer.

In one embodiment, deposition of isolation layer 110 may be accomplished with a plasma torch. A plasma torch is akin to a remote plasma source that is equipped with internal means for generating a plasma from a source gas and which delivers an energized deposition medium to a surface for deposition.

The plasma torch includes an anode and cathode between which a voltage is applied. The plasma torch further includes an inlet for receiving a source gas and an outlet for delivering an energized deposition medium to a deposition chamber. A plasma is formed within the plasma torch from the source gas in the region between the anode and cathode. The region between the anode and cathode may be referred to herein as the plasma region of the plasma torch. The outlet of the plasma torch may be spaced apart from the plasma region.

The source gas is supplied to the plasma region as a flowing stream and has kinetic energy of motion. The motion of the source gas is preferably directed toward the outlet. The source gas remains in motion as it is converted to a plasma in the plasma region and exits the plasma region in a moving state. When the plasma exits the plasma region, it deactivates to a lower energy state. The deactivated state may possess a reduced concentration of charged species relative to the state of the source gas while in the plasma region. The deactivated remains, however, energized relative to the state in which it was initially supplied to the plasma region. The energized state may contain charged species and/or neutral species, where the neutral species exist in an excited electronic state. The energized state facilitates formation of thin film materials by increasing deposition rate. In one embodiment, the source gas in its deactivated state constitutes a deposition medium that may be transported from the plasma torch to a substrate for deposition of isolation layer 110.

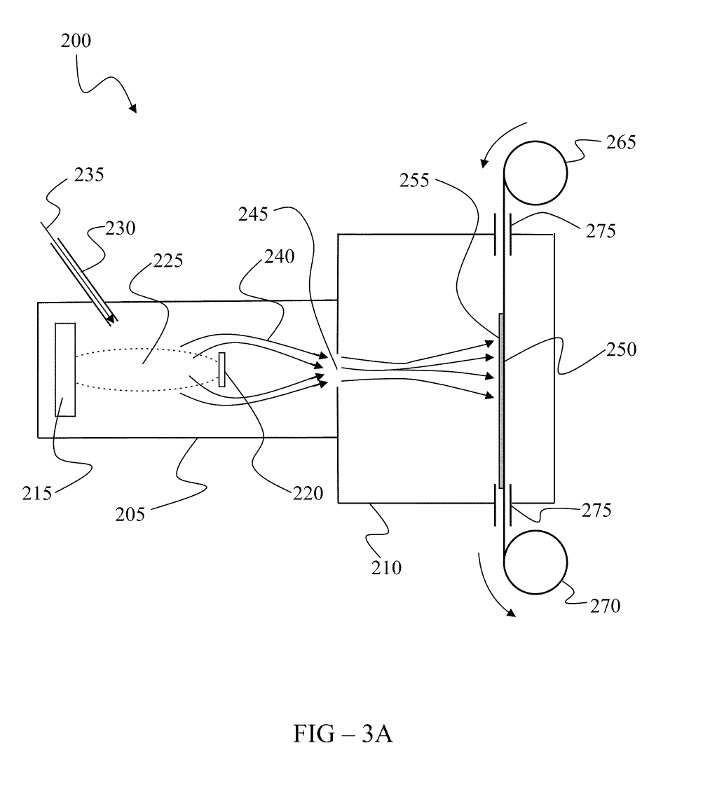

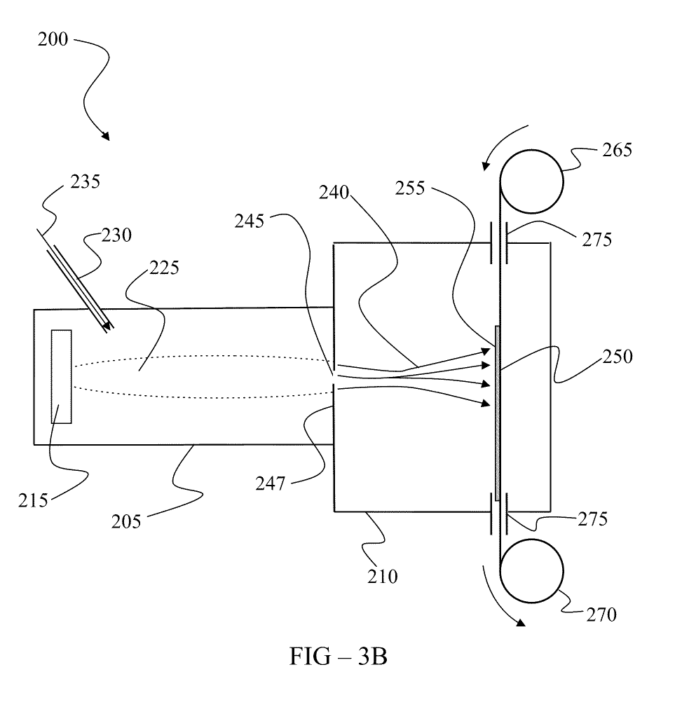

FIG. 3A depicts an embodiment of a deposition chamber equipped with a plasma torch. Deposition apparatus 200 includes plasma torch 205 interconnected to deposition chamber 210. Plasma torch 205 includes first electrode 215 and second electrode 220 with plasma region 225 formed therebetween. Plasma torch 205 further includes inlet 230 for delivering source gas 235. Source gas 235 enters plasma region 225 and exits as deactivated medium 240 that enters deposition chamber 210 through opening 245. Deactivated medium 240 is charge depleted and continues toward substrate 250 whereupon thin film material 255 is formed. Substrate 250 is a continuous web substrate and is in motion during deposition. Substrate 250 is delivered to deposition chamber 210 by payout roller 265 and received by take up roller 270 after deposition of thin film material 255. Continuous web substrate 250 enters and exits deposition chamber 210 through isolation devices 275. Isolation devices 275 may be, for example, gas gates.

A pressure differential between plasma torch 205 and deposition chamber 210 may facilitate motion of deactivated medium 240. If the pressure within deposition chamber 210 is less than the pressure within plasma torch 205, deactivated medium 240 is accelerated toward continuous web substrate 250 as it exits opening 245. In one embodiment, the pressure within deposition chamber 210 is at least a factor of 10 less than the pressure within plasma torch 205. In another embodiment, the pressure within deposition chamber 210 is at least a factor of 100 less than the pressure within plasma torch 205. In a further embodiment, the pressure within deposition chamber 210 is at least a factor of 1000 less than the pressure within plasma torch 205.

In another embodiment, the deactivated plasma may be further modified before exiting the plasma torch. In this embodiment, the outlet of the plasma torch is configured as a restricted orifice, such as a nozzle, that acts to confine the deactivated plasma. In the embodiment of FIG. 3A, for example, opening 245 may be constricted to form a narrow orifice or equipped with a nozzle to regulate the flow of deactivated deposition medium 240 into deposition chamber 210. Confinement constricts the volume of the deactivated plasma, reduces the average separation between species in the deactivated plasma, and alters the distribution of species present in deactivated deposition medium 240.

FIG. 3B shows a modification of the embodiment shown in FIG. 3A in which second electrode 220 is removed and instead, backplane 247 of plasma torch 205 is used as an electrode in the formation of plasma region 225. As in the embodiment of FIG. 3A, opening 245 may be constricted to confine the plasma as it exits remote plasma source 205 and deactivates to form charge-depleted deposition medium 240 upon entry into deposition chamber 210. Opening 245 may also be fitted with a nozzle. The nozzle may serve as an electrode in combination with backplane 247 or may function as an electrode independent of backplane 247.

A wide variety of source gases is compatible with the operation of plasma torch 205 to form isolation layer 110. Silicon source gases include SiH₄, Si₂H₆, and SiX₄, where X is a halide. Mixed halide and mixed halide-hydrogen silicon source gases may also be used. The silicon source gas may be mixed with or co-injected into plasma torch 205 with O₂, H₂O, ozone, or other oxygen-containing source gas to form SiO₂. SiO₂ may also be formed from an oxygenated silicon source gas such as TEOS (Si(OC₂H₅)₄) or TMOS (Si(OCH₃)₄). Silicon nitride may be formed by mixing or co-injecting a silicon source gas with N₂, NH₃, NF₃, or other nitrogen-containing source gas. Silicon nitride may also be formed from a nitrogenated silicon source gas such as Si(N(CH₃)₃)₄. Silicon oxynitride may be formed from a silicon source gas in combination with an oxygen-containing gas and a nitrogen-containing gas. Alternatively, silicon oxynitride may be formed from an oxygenated silicon source gas and a nitrogen-containing source gas or from a nitrogenated silicon source gas and an oxygen-containing source gas.

In general, a dielectric metal oxide may be formed with plasma torch 205 from a combination of a metal halide source gas and an oxygen-containing source gas. Dielectric metal nitrides may be formed with plasma torch 205 from a combination of a metal halide source gas and a nitrogen-containing source gas. Precursors used in chemical vapor deposition or plasma-enhanced chemical vapor deposition processes are typically suitable source gases for delivering elements for forming isolation layer 110 using plasma torch 205. Although not explicitly shown in FIGS. 3A and 3B, it is understood that plasma torch 205 may be equipped with multiple inlets to receive multiple source gases for forming multi-element compositions. Alternatively, multiple source gases may be combined and delivered as a single inlet stream. The inlet stream may further include a diluent gas such as argon.

After deposition of isolation layer 110, a back reflector layer is formed. FIG. 2C shows back reflector layer 112 formed over substrate 105 and on isolation layer 110. Back reflector layer 112 improves the photovoltaic conversion efficiency by reflecting electromagnetic radiation that passes through active photovoltaic material 120. Reflection returns the electromagnetic radiation back to photovoltaic material 120 to increase the utilization and reduce losses. The back reflector is preferably textured to facilitate light trapping and minimize scattering or reflection of radiation to the exterior of the device.

Back reflector layer 112 also serves as a lower electrode for devices in module 100 and may be formed from any reflective material that is capable of conducting an electrical current. Back reflector layer 112 may be a single material or a composite material. Representative back reflector materials include metals (e.g. aluminum (Al), silver (Ag), copper (Cu), conductive oxides (e.g. ZnO, ITO), or conductive chalcogenides (e.g. ZnS, ZnTe, ZnSe, CdS). Composite back reflectors include two or more materials arranged as layers or as a dispersion of one material within another. Composite back reflectors may includes a conductive oxide and a metal, a conductive chalcogenides and a metal, a conducive oxide and conductive chalcogenides, or any combination of conductive materials generally that provides adequate reflectivity. Representative composite back reflectors include ZnO/Al, ZnO/Ag, ZnS/Al, and ZnS/Ag. Back reflector layer 112 is typically formed via a vacuum or reduced pressure deposition technique such as sputtering, evaporation, or chemical vapor deposition. Back reflector layer 112 may also be formed using a plasma torch, such as plasma torch 205 described hereinabove in connection with FIGS. 3A and 3B, using a gas phase deposition precursor (e.g. ZnR₂ or AlR₃, where R is an alkyl group (e.g. methyl, ethyl, propyl); or ZnX₂ or AlX₃, where X is a halide group (e.g. Cl, Br). Deposition in the presence of, or co-deposition with, oxygen or an oxygen-containing gas permits formation of an oxide. Preparation of back reflector layer 112 with a plasma torch is accomplished under vacuum or reduced pressure conditions and may be performed in the presence of a background, diluent, or carrier gas (e.g. Ar, He, Ne, N₂, H₂).

Back reflector layer 112 is formed as a continuous layer and subsequently patterned. Patterning entails segmenting back reflector layer 112 to form a series of electrically isolated back reflector regions 115 (FIG. 2D). As described hereinbelow, the active photovoltaic material and upper transparent conductive layer may also be patterned. Patterned combinations of a back reflector, active photovoltaic material, and top electrode represent a plurality of individual photovoltaic devices that are connected in series to achieve monolithic integration.

Patterning includes the selective formation of features 117 (e.g. trenches or vias) that define and spatially separate individual back reflector regions 115. Patterning of back reflector layer 112 may be accomplished by laser scribing, a process in which a laser is used to selectively remove material in a predetermined pattern in one or more of layers of a device structure. An excimer or other ablative laser may be used for laser scribing. The power of the laser, wavelength, depth of focus, and exposure time are carefully controlled to ablate the back reflector material to form patterned features 117 without affecting underlying layers. The material removed via laser scribing of back reflector layer 112 exposes isolation layer 110 to achieve segmentation of back reflector layer 112 and form electrically isolated back reflector regions 115. Like all steps in the fabrication of the instant devices, laser scribing may be formed in a continuous manufacturing process.

In an alternative embodiment, patterning of back reflector layer may be accomplished through a masking and etching process, such as is known in the art of photolithography, where a variety of negative and positive resist chemistries are known. In a typical process, a resist material is first formed on the surface of back reflector layer 112. The resist material is then patterned by superimposing a mask over the resist, where the mask represents the positive or negative image of the desired pattern. The unmasked portions of the resist are then chemically or photochemically modified to create a solubility contrast between the masked and unmasked portions of the resist. Depending on the particular chemistry, either the masked or unmasked portions of the resist are removed to expose a portion of back reflector layer 112. The exposed portions of back reflector layer 112 may then be processed selectively relative to the unexposed portions to form a pattern. Selective processing of back reflector layer 112 typically includes a chemical etch designed to exploit differences in solubility of the exposed and unexposed portions.

Photovoltaic material 122 is formed on patterned back reflector regions 115 and fills patterned features 117 (FIG. 2E). Photovoltaic material 122 may be any material or combination of materials capable of generating a photocurrent upon absorption of incident solar or electromagnetic radiation. Representative photovoltaic materials include CdS, CdSe, CdTe, ZnTe, ZnSe, ZnS, CIGS (Cu—In—Ga—Se and related alloys), organic materials (including organic dyes), and TiO₂ or other metal oxides, including doped or activated forms thereof.

Silicon-based materials are another prominent class of photovoltaic materials. Silicon-based materials include amorphous silicon (a-Si), alloys of amorphous silicon (e.g. amorphous silicon-germanium alloys), nanocrystalline silicon, nanocrystalline alloys of silicon, microcrystalline silicon, microcrystalline alloys of silicon. Silicon-based photovoltaic materials include fluorinated or hydrogenated forms thereof. Silicon-based photovoltaic materials may also be rendered n-type or p-type through appropriate doping. Column III elements (e.g. B) may be used as p-type dopants and column V elements (e.g. P) may be used as n-type dopants.

Multilayer photovoltaic materials may be formed from a combination of two or more photovoltaic materials, including two or more alloys that differ in the relative proportions of the constituent atoms. Multilayer photovoltaic materials may include n-type, i-type (intrinsic type), or p-type layers. In one embodiment, the photovoltaic material is a p-i-n device. A p-i-n device is a sequence of layers that includes a p-type material, an intrinsic or i-type material, and an n-type material. A representative p-i-n device includes a p-type microcrystalline silicon layer, an i-type amorphous silicon or amorphous silicon-germanium layer, and an n-type amorphous or microcrystalline silicon layer. Two or more p-i-n (or n-i-p) structures may be stacked in series on patterned back reflector regions 115 to achieve multiple junction device structures. The tandem (dual junction) and triple junction cells known in the prior art, for example, include two and three p-i-n (or n-i-p) structures in series, respectively.

For improved absorption of the solar spectrum, the bandgaps of the different intrinsic layers of multi junction devices may differ. As an example, a first i-type layer may include amorphous silicon, a second i-type layer may include an amorphous silicon-germanium alloy with a particular proportion of germanium relative to silicon, and a third i-type layer may include an amorphous silicon-germanium alloy with a different proportion of germanium relative to silicon. Individual layers of single or multilayer device structures may also achieve bandgap tuning by incorporating graded compositions. Bandgap tuning may be achieved, for example, by grading the composition of the intrinsic layer of a p-i-n structure over a range of different proportions of silicon and germanium. Other multilayer device structures in accordance with the instant invention include pn devices or np devices. Although photovoltaic material 122 is shown as a uniform element in FIG. 2E, it is understood that this depiction is for convenience of illustration and that photovoltaic material 122 may be either a single layer or multilayer structure as described hereinabove.

Methods for forming photovoltaic material 122 (or surrounding n-type or p-type layers) include a solution deposition process (e.g. sol-gel process), a chemical vapor deposition process (including MOCVD, PECVD (at radiofrequencies or microwave frequencies), or a physical vapor deposition process (e.g. evaporation, sublimation, sputtering). Representative vapor phase deposition precursors for photovoltaic materials based on silicon, germanium, and silicon-germanium alloys include SiH₄, Si₂H₆, GeH₄, and Ge₂H₆. Fluorination may be achieved via fluorinated precursors (e.g. SiFₓH₄₋ₓ (x=1-4) or GeFₓH₄₋ₓ (x=1-4)) or a fluorine additive (e.g. HF, F₂, CF₄, NF₃). Photovolatic material 122 may also be formed using a plasma torch, such as plasma torch 205 described hereinabove in connection with FIGS. 3A and 3B, using a gas phase deposition precursor. Preparation of photovoltaic material 122 with a plasma torch is accomplished under vacuum or reduced pressure conditions and may be performed in the presence of a background, diluent, or carrier gas (e.g. Ar, He, Ne, N₂, H₂).

Photovoltaic material 122 is next patterned. Patterning entails segmenting photovoltaic material 122 to form a series of electrically isolated photovoltaic regions 125 (FIG. 2F). Patterning includes the selective formation of features 127 (e.g. trenches or vias) that define and spatially separate individual photovoltaic regions 125. Patterning of photovoltaic material 122 may be accomplished as described hereinabove with respect to back reflector layer 112 by laser scribing or masking and etching techniques. The patterning process is carefully controlled to form patterned features 127 without affecting underlying layers. The material removed upon patterning photovoltaic material 122 exposes patterned back reflector regions 115. Patterned features 127 are staggered relative to patterned features 117 described hereinabove.

Transparent conductive material 132 is formed on patterned photovoltaic regions 125 and fills patterned features 127 (FIG. 2G). Transparent conductive material 132 is a material providing sufficient transmission of incident solar or electromagnetic radiation and adequate conductivity to insure efficient mobility of photogenerated charge carriers produced in the active photovoltaic material. Transparent conductive materials are typically metal oxides prepared by a sputtering, reactive sputtering, solution deposition, pulsed laser deposition, spray pyrolysis, evaporation, or chemical vapor deposition technique. Representative transparent conductive materials include tin oxide (SnO₂), indium oxide (In₂O₃), ITO (indium tin oxide), zinc oxide (ZnO), zinc tin oxide (ZnSnO₃, Zn₂SnO₄), and cadmium tin oxide (Cd₂SnO₄). Transparent conductive materials may be doped with elements such as F, Al, Ga, In, B, and Sn to boost conductivity. Transparent conductive material 132 may also be formed using a plasma torch, such as plasma torch 205 described hereinabove in connection with FIGS. 3A and 3B, using a gas phase deposition precursor. Gas phase precursors include metal alkyls (e.g. Cd(CH₃)₂, Zn(CH₃)₃, In(CH₃)₃, Sn(CH₃)₄) or metal halides (e.g. SnCl₄, InCl₃) of Preparation of transparent conductive material 132 with a plasma torch is accomplished under vacuum or reduced pressure conditions and may be performed in the presence of a background, diluent, or carrier gas (e.g. Ar, He, Ne, N₂, H₂).

Transparent conductive material 132 is next patterned. Patterning entails segmenting transparent conductive material 132 to form a series of electrically isolated transparent electrode regions 135 (FIG. 2H). Patterning includes the selective formation of features 137 (e.g. trenches or vias) that define and spatially separate individual transparent electrode regions 135. Patterning of transparent conductive material 132 may be accomplished as described hereinabove with respect to back reflector layer 112 by laser scribing or masking and etching techniques. The patterning process is carefully controlled to form patterned features 137 through transparent conductive material 132 and through patterned photovoltaic regions 125 without affecting underlying layers. The material removed upon patterning transparent conductive material 132 exposes patterned back reflector regions 115. Patterned features 137 are staggered relative to patterned features 127 and patterned features 117 described hereinabove. As noted hereinabove, patterned back reflector regions 115, patterned photovoltaic regions 125, and patterned transparent electrode regions 135 define a series of individual devices that are connected in series.

Protective layer 142 is next formed over patterned transparent electrode regions 135 and fills patterned features 137 (FIG. 2J). Protective layer 142 is also formed on the lateral edges of the device structure. Protective layer 142 is intended to protect the device structure from atmospheric or environmental contaminants such as oxygen or water that may degrade photovoltaic performance over time. Protective layer 142 is a thin layer that efficiently transmits incident solar or other electromagnetic radiation to underlying patterned transparent electrode regions 135. Representative materials for protective layer 142 include silicon-based polymers (e.g. silicone, polysiloxane) or carbon-based polymers (e.g. Teflon, Tefcell (a polymer made from partially fluorinated ethylene), polyethylene, polycarbonate, ethylvinylacetate).

Protective layer 142 is preferably formed with a plasma torch, such as plasma torch 205 described hereinabove. Source gases include SiH₄, alkanes (e.g. CH₄, C₂H₆, C₃H₈), and alkenes (e.g. C₂H₄). Supplemental oxygen-containing source gases may also be employed to obtain oxygenated protective layers. Fluorinated protective layers may be formed from fluorinated silane, fluorinated alkanes, or fluorinated alkenes. A benefit of the instant invention is that use of a plasma torch permits formation of protective layer 142 at ambient pressure, without a need for establishing a reduced pressure or vacuum environment. In a further embodiment, protective layer 142 may be formed with a plasma torch in air, without a need to provide a protected, isolated deposition environment. The high rates and simplified conditions of deposition available from a plasma torch provide a significant economic advantage in forming protective layer 142.

In a further step, a laminate material may be applied to the backside of the substrate to provide additional durability. FIG. 2K shows laminate 152 applied to the backside of substrate 105. Laminate 152 may be any material capable of providing mechanical support to the multilayer photovoltaic device. Representative materials for the laminate include plastics and fiberglass. In one embodiment, the laminate is a pre-formed sheet of material that is applied to the backside of substrate 105. The laminate may include an adhesive to facilitate affixation to the substrate.

FIG. 2L shows module 100 after a finishing step. Finishing includes cutting the continuous web into sheets of desired length, insulating the exposed ends produced by cutting, and providing external contacts. Package electrodes 162 are formed by removing end portions of protective layer 142 to expose patterned transparent electrodes 135 and depositing a conductive material that contacts patterned transparent electrodes 135. Package electrodes 162 permit delivery of the electrical current produced by module 100 to an external load. At this stage of fabrication, module 100 includes a plurality of photovoltaic devices connected in series. The arrows shown in FIG. 2M (and FIG. 1) illustrate the general path of current flow through the series of devices.

Those skilled in the art will appreciate that the methods and designs described above have additional applications and that the relevant applications are not limited to the illustrative examples described herein. The present invention may be embodied in other specific forms without departing from the essential characteristics or principles as described herein. The embodiments described above are to be considered in all respects as illustrative only and not restrictive in any manner upon the scope and practice of the invention. It is the following claims, including all equivalents, which define the true scope of the instant invention.

We claim:

1. A method of forming a thin film device comprising:
providing a substrate;
forming a first layer over said substrate, said first layer being formed from a first deposition medium at a pressure of ambient pressure or greater; and
forming a second layer over said substrate, said second layer being formed from a second deposition medium at a pressure below ambient pressure.

2. The method of claim 1, wherein said substrate comprises a metal.

3. The method of claim 1, wherein said first layer comprises a dielectric material.

4. The method of claim 3, wherein said first layer comprises an oxide or nitride.

5. The method of claim 1, wherein said first layer comprises a polymer.

6. The method of claim 5, wherein said polymer comprises carbon.

7. The method of claim 6, wherein said polymer further comprises fluorine.

8. The method of claim 1, wherein said first deposition medium comprises silicon.

9. The method of claim 1, further comprising forming said first deposition medium from a first gas phase precursor.

10. The method of claim 9, further comprising forming a first plasma from said first gas phase precursor.

11. The method of claim 10, wherein said first gas phase precursor comprises silicon, carbon, fluorine, or hydrogen.

12. The method of claim 10, further comprising deactivating said first plasma, said first deposition medium comprising said deactivated first plasma.

13. The method of claim 10, wherein said first layer is formed from said first deposition medium in the presence of air.

14. The method of claim 10, wherein said first layer is formed from said first deposition medium in the presence of an oxygen-containing gas.

15. The method of claim 10, wherein said first layer is formed from said first deposition medium in the presence of a nitrogen-containing gas.

16. The method of claim 10, wherein said second layer comprises a photovoltaic material.

17. The method of claim 10, wherein said second deposition medium comprises silicon.

18. The method of claim 17, wherein said second layer comprises said silicon.

19. The method of claim 18, wherein said silicon is in the form of amorphous silicon, nanocrystalline silicon, or microcrystalline silicon.

20. The method of claim 10, further comprising forming said second deposition medium from a second gas phase precursor.

21. The method of claim 20, wherein said second gas phase precursor comprises silicon or germanium.

22. The method of claim 20, wherein said second gas phase precursor comprises hydrogen or fluorine.

23. The method of claim 20, wherein said second gas phase precursor comprises Te, Se, S, Cd, Zn, In, or Ga.

24. The method of claim 20, further comprising forming a second plasma from said second gas phase precursor.

25. The method of claim 24, further comprising deactivating said second plasma, said second deposition medium comprising said deactivated second plasma.

26. The method of claim 1, further comprising forming a back reflector, said back reflector being disposed between said substrate and said first layer.

27. The method of claim 26, wherein said back reflector comprises a metal oxide, said metal oxide include a first metal.

28. The method of claim 27, wherein said back reflector further comprises a second metal.

29. The method of claim 26, further comprising patterning said back reflector.

30. The method of claim 29, wherein said second layer directly contacts said back reflector.

31. The method of claim 30, further comprising patterning said second layer.

32. The method of claim 31, further comprising forming a transparent conductive material over said second layer.

33. The method of claim 32, wherein said transparent conductive material directly contacts said second layer.

34. The method of claim 32, wherein said transparent conductive material is an oxide.

35. The method of claim 34, wherein said oxide comprises zinc, indium or tin.

36. The method of claim 32, further comprising patterning said transparent conductive layer.

37. The method of claim 36, wherein said patterning of said back reflector, said patterning of said second layer, and said patterning of said transparent conductive layer forms a plurality of photovoltaic devices.

38. The method of claim 37, wherein said plurality of photovoltaic devices are connected in series.

39. The method of claim 37, further comprising forming a protective layer over said patterned transparent conductive layer.
